(19) United States
(12) Patent Application Publication
(10) Pub. No.: US 2018/0240614 A1
(43) Pub. Date: Aug. 23, 2018

(54) MECHANISMS TO RESET CIRCUIT BREAKERS

(71) Applicant: Hewlett Packard Enterprise Development LP, Houston, TX (US)

(72) Inventors: Matthew E. Stevens, Houston, TX (US); Chris F. Felcman, Magnolia, TX (US); Scott Edwards Holloway, Houston, TX (US)

(73) Assignee: Hewlett Packard Enterprise Development LP, Houston, TX (US)

(21) Appl. No.: 15/752,287

(22) PCT Filed: Aug. 14, 2015
(86) PCT No.: PCT/US2015/045376

§ 371 Date: Feb. 13, 2018

(51) Int. Cl. H01H 3/28; H05K 7/18; H05K 7/14; H01H 3/54

(52) U.S. Cl. CPC H01H 3/28; H01H 3/54; H05K 7/1492; H05K 7/183

(57) ABSTRACT

An example device in accordance with an aspect of the present disclosure includes a housing, mountable to a power distribution unit (PDU) associated with at least one circuit breaker. The device also includes a mechanism coupled to the housing, movable between a first position and a second position to reset the at least one circuit breaker, in response to receiving a reset signal.

### BACKGORUND

Datacenter racks can include power distribution units (PDUs) that have circuit breakers, to deliver power to various components installed in the rack. If a PDU circuit breaker trips, it needs to be reset to restore power to affected components. The PDU can be difficult to access within the rack, and may require partial disassembly of the rack or removal of components to access and reset tripped circuit breakers of the PDU.

### BRIEF DESCRIPTION OF THE DRAWINGS/FIGURES

FIG. 1 is a block diagram of a device including a housing and a mechanism according to an example.

FIG. 2 is a block diagram of a system including a housing and a power distribution unit (PDU) according to an example.

FIG. 3A is a perspective exploded view of a device including a housing and a mechanism according to an example.

FIG. 3B is a perspective view of a device including a housing and a mechanism according to an example.

FIG. 4A is a perspective view of a system including a housing and a PDU according to an example.

FIG. 4B is a perspective view of a rack including a PDU according to an example.

FIG. 4C is a perspective view of a rack including a PDU according to an example.

FIG. 5 is a flow chart based on moving a mechanism according to an example.

### DETAILED DESCRIPTION

A computer server or other equipment can use a power distribution unit (PDU) or units to provide power to components, which are protected using circuit breakers in the PDU. However, if a circuit breaker trips in the PDU, a technician is typically needed to physically visit the equipment, gain access to the PDU, and physically reset the circuit breaker by hand. However, the PDU can be located within a rack of a computer server such that access to the PDU is blocked by other components. Thus, gaining access to the circuit breakers of the PDU can be difficult, involving disassembly of the server and/or components (e.g., needing to remove side panels of the rack). The rack and PDU can be based on compact form factors, whereby the circuit breakers need to be compact to fit sufficient number of circuit breakers to meet amperage needs of the system, thereby preventing the use of remotely-resettable circuit breakers that are bulky and incompatible with compact PDU form factors.

To address such issues, examples described herein may provide a mechanism coupled to the housing, movable between a first position and a second position to reset the at least one circuit breaker, in response to receiving a reset signal. In this manner, examples described herein enable a circuit breaker remote reset option for PDUs, to remotely reset a circuit breaker on a PDU. Thus, examples described herein make it possible to reset circuit breakers on PDUs that are not easily accessible within a datacenter/computing system rack.

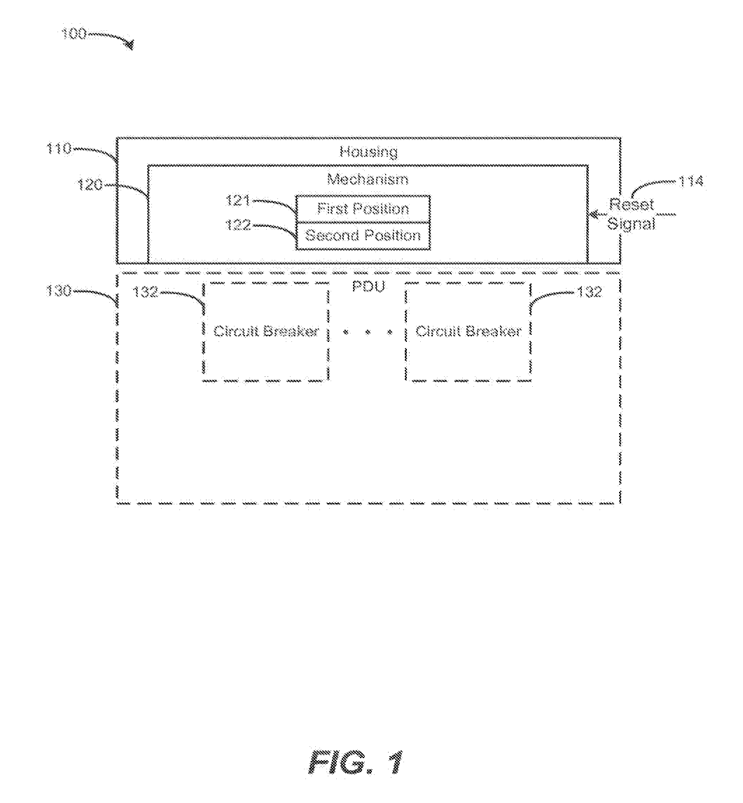

FIG. 1 is a block diagram of a device 100 including a housing 110 and a mechanism 120 according to an example. The housing 110 is mountable to a PDU 130, which includes at least one circuit breaker 132. The mechanism 120 is movable between a first position 121 and a second position 122 to reset the circuit breaker(s) 132, in response to a reset signal 114. The housing 110 end device 100 can be attached to an existing PDU 130, e.g., provided as an expansion option for a line of PDUs. For example, the housing 110 can include thumbscrews to attach the housing 110 to the PDU 130 as an option. In alternate examples, the housing 110 may be integrated with a PDU 130 as a signal unit.

The mechanism 120 is operable between states based on receiving the reset signal 114. The reset signal 114 can be generated from a remote switch (not shown), which can be installed at the server (e.g., on a rack door of the server) for easy access by a technician at the server. In alternate examples, the reset signal 114 can be generated by the PDU 130, e.g., where the PDU 130 is a smart PDU 130 receiving commands over a network such as a local area network (LAN) and/or the Internet. The reset signal 114 enables the mechanism to move from the first position 121 to the second position based on a remote signal, to reset a tripped circuit breaker 130. For example, a user having appropriate administrative rights to a smart PDU 130 can select a breaker reset command option in a remote management console of the smart PDU 130, to activate the mechanism 120. The mechanism 120 can be based on various approaches, inducting a solenoid motor to move gears having extensions to reset the tripped circuit breakers 132. In alternate examples, the mechanism 120 can be based on linkages, servos, and other techniques compatible with actuating a reset switch to reset the circuit breakers 132.

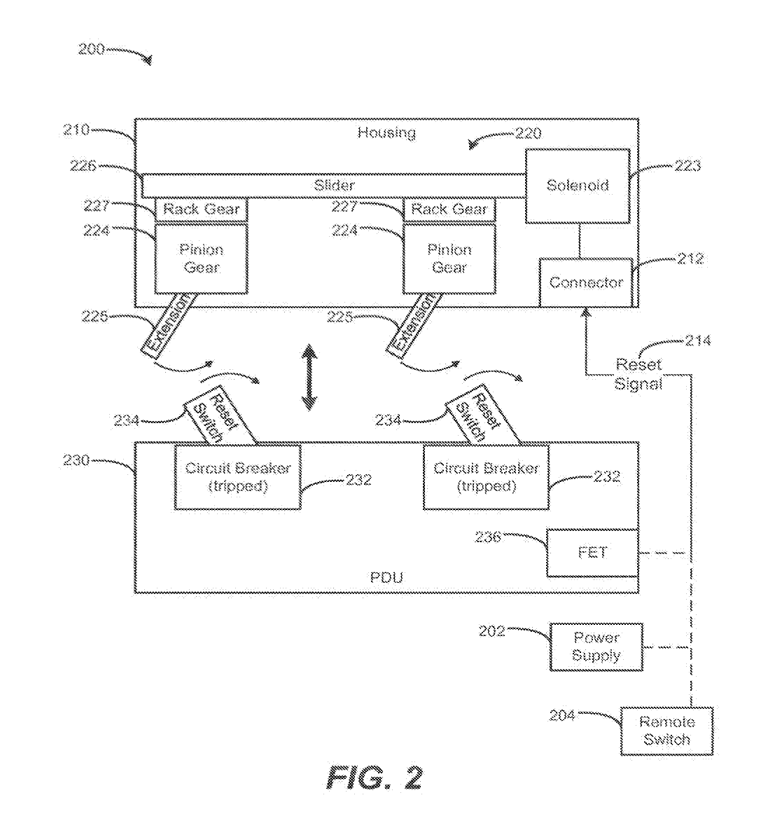

FIG. 2 is a block diagram of a system 200 including a housing 210 and a power distribution unit (PDU) 230 according to an example. The housing includes a connector 212 and a mechanism 220. The mechanism 220 includes solenoid 223, slider 226, rack gears 227, pinion gears 224, and extensions 225. The PDU 230 includes FET 236 and circuit breakers 232, which include reset switches 234. The connector 212 of the housing 210 is to receive the reset signal 214 from various sources, such as the FET 236, an external power supply 202, and/or a remote switch 204.

The system 200 illustrates a removable option for providing remote circuit breaker reset, which can attach to a chassis of an existing PDU. The connector 212 can provide power to the mechanism 220/solenoid 223. Such operational power can be obtained from the PDU 230, power supply 202, remote switch 204, or other sources, to activate the solenoid 223 to actuate the slider 226, rack gears 227, and pinion gears 224 to reset the circuit breaker switch 234 in response to the reset signal 214. In an example, the reset signal 214 may be provided as a power signal to power the solenoid 223. The housing 210 can induce alignment pins and/or other attachment features (e.g., thumbscrews) to ensure proper alignment between the housing 210 and the PDU 230. In an alternate example, the housing 210 can be integrated with the PDU 230.

Components of system 200 can be formed of various materials. For example, the extension 225 and gears 224, 227 can be molded and/or die-cast, from materials of sufficient rigidity to actuate the reset switches 234 of the circuit breakers 230. For example, materials such as plastics, metals, alloys, and so on (e.g., zinc alloy metal). The components can be keyed to allow assembly in the proper manner. For example, the pinion gears 224 can be keyed to align the extensions 225 synchronized with each other and located in the proper position for actuating the reset switches 234. The extensions 225 are shown in a first position, ready to reset the tripped circuit breakers 232 by moving toward a second position as indicated by the curved arrows. Notably, the extensions 225 do not impede or otherwise interfere with the normal operation of the circuit breakers 232, enabling the circuit breakers 232 to trip freely as needed.

The example of FIG. 2 shows two pinions gears 224 corresponding to two circuit breakers 232. Alternate example devices 200 can be based on a single gear/extension, or systems of three or more gears/extensions, (e.g., six) corresponding to a particular design of a given PDU. A system of multiple circuit breakers 232 and/or PDUs 230 can be actuated by one or more devices 200. For example, one housing 210 can include a linear arrangement of six pinion gears 224 and corresponding extensions 225, to actuate six circuit breakers 232. Alternatively, a set of two devices, each including three pinion gears 224, can be installed at such a PDU 230 having six circuit breakers. A device 200 may include a plurality of components, such as multiple solenoids 223 and/or sliders 226 within the same housing 210. In an example, a plurality of solenoids 223 may be provided in a housing 210, to enable one solenoid 223 per pinion gear 224 (e.g., for increased torque per gear).

The extensions 225 are shaped to interact with the reset switches 234 of the given type of circuit breakers 232. For example, the reset switches 234 can be provided as rocker switches, which can be actuated by the sweeping motions of the extensions 225 that rotate with the pinion gears 224. In alternate examples, the circuit breakers 232 may include reset switches 234 that are based on actuators that are retracted when untagged, and that extend out of the circuit breaker 232 when tripped. For such types of circuit breakers 232, the extension 225 may be formed as a linkage to link with the circuit breaker actuator and provide a sliding motion (in contrast to the illustrated sweeping/pushing motion).

The extensions 225 in the illustrated first position do not interfere with the reset switches 234 of the circuit breakers 232, when the reset switches 234 are in an untripped position (and also when the switches/extensions are actuating). The reset switches 234 can be formed as flat rocker switches that, when untripped to complete an electrical circuit, remain flush with the surface of the circuit breaker 232 and external panel of the PDU 230. Thus, for an untripped circuit breaker 232 among a group of tripped circuit breakers 232, the corresponding extension 225 can pass over the untripped reset switch 234 without affecting it. Thus, the circuit breakers 232 can be tripped or reset collectively/simultaneously, or one at a time, without impeding or otherwise preventing the circuit breakers 232 from tripping as-needed.

The solenoid 223 can be provided as a 12 Volt or other rating of solenoid motor. The solenoid 223 can be rated to provide sufficient force to actuate a desired number of extensions 225 for resetting a corresponding number of circuit breakers 232 (e.g., in the case where the plurality of the circuit breakers 232 are tripped in a given installation). The solenoid 223 can be arranged, via the slider 226 and/or rack gears 227, to actuate from the first position to the second position by pushing and/or pulling, and can be biased to spring back from the second position to the first position.

The connector 212 receives the reset signal 214 to actuate the mechanism 220. For example, the connector 212 can supply momentary power (e.g., a second or two) to actuate the solenoid 223 to move from the first position to the second position to reset the circuit breakers 232, and then release and return to the first position. The connector 212 (or other suitable connector not specifically shown) can be used to sense whether the assembly/housing 210 is attached to the PDU 230. The PDU 230 (e.g., a smart PDU) similarly can sense whether the mechanism 220 is present and available for automatically resetting the circuit breakers 232, and provide a notification accordingly (e.g., indicating, in a smart user interface or other firmware option, that remote reset is available when the mechanism 220 is installed and detected at the PDU 230). Such a smart PDU 230 can identify power loss and activate the mechanism 220 as needed automatically, while safely confirming that the circuit breakers 232 are not constantly tripping once reset (which would indicate a serious problem where the circuit breakers 232 are to remain tripped until they can be serviced by a technician). The smart PDU 230 can include its own power supply to power its electronics as well as to generate the reset signet 214.

The PDU can include a switch, such as a field-effect transistor (FET) 236, operable electrically by circuitry of the PDU 230. For example, the PDU can receive a notification signal over a network, and trigger the FET 236 to provide the reset signal 214 in the form of momentary power to the solenoid 223. The reset signal 214 can be asserted by various techniques, including network message, text message, Internet message, manual switch, and so on. The smart PDU 230 also can include power metering capabilities to inform a user when power is lost and the circuit breakers 232 are tripped. The user can then browse the internet into an address for the smart PDU 230 and issue a command to cause the FET 236 to issue the reset signal 214 and actuate the mechanism 220 to reset the circuit breakers 232.

The reset signal 214 also can be provided via a power supply 202 and/or remote switch 204. For example, the power supply 202 can include an extension cable coupled to the connector 212 of the housing 210, and also coupled to a remote switch 204. The remote switch 204 can be operable to selectively couple the remote power supply 202 to the connector 212, thereby providing the reset signal 214. The remote switch 204 can be positioned in a convenient location, near to or at a server, for example. Thus, a user can manually actuate the remote switch 204 to activate the mechanism 220 and reset the circuit breakers 232. The remote switch 204 (and/or power supply 202) can be positioned in a convenient location, such as a front-side of the rack (e.g., the rack door) or other location conveniently accessible without a need to partially of fully disassemble the rack.

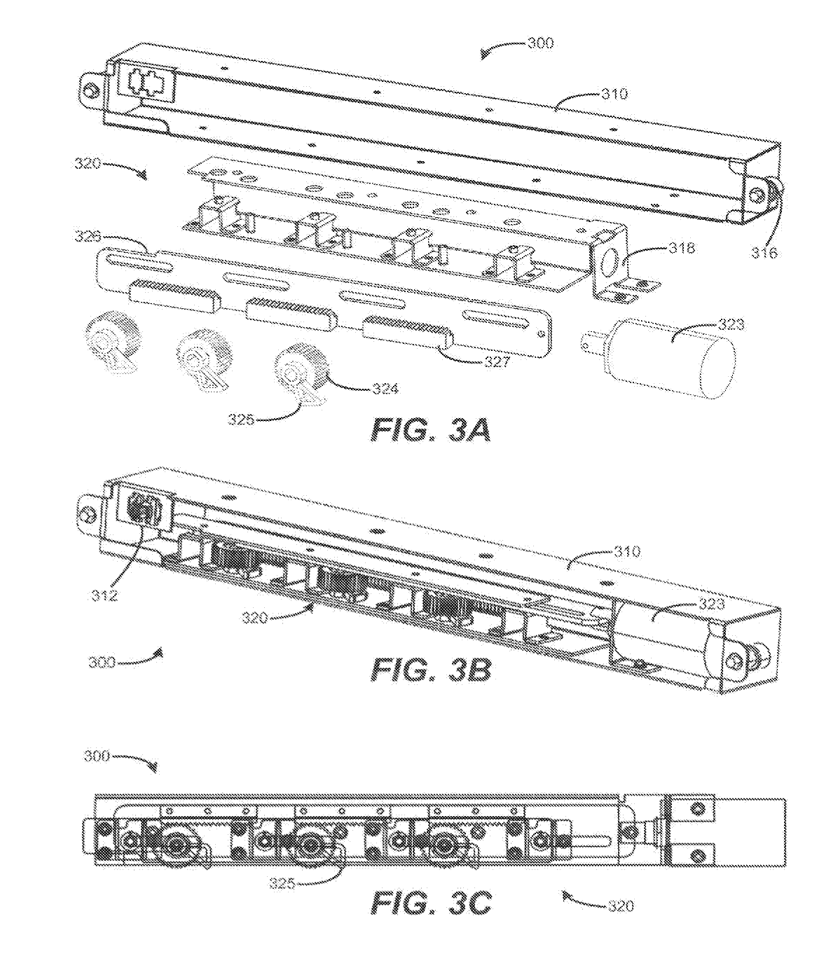

FIG. 3A is a perspective exploded view of a device 300 including a housing 310 and a mechanism 320 according to an example. Various components of the mechanism 320 can be coupled inside the housing 310, to form the assembled device 300 shown in FIG. 3B. Bracket 318 can be mounted in the housing 310, and the slider 326, pinion gears 324, and solenoid 323 can be mounted to the bracket 318. The slider 326 can be slidably mounted relative to the bracket 318 and housing 310, enabling the solenoid 323 to slidably move the slider 326 back and forth. The slider 320 includes rack gears 327, corresponding to the number of pinion gears 324 rotatably mounted to the bracket 318. Thus, lateral motion of the slider 326 under control of the solenoid 323 causes the rack gears 327 to impart rotational movement to the pinion gears 324. Each example pinion gear 324 is shown including a corresponding extension 325. The example extension 325 is formed as a triangular shape. Accordingly, the extension 325 can be rotated to reset a tripped circuit breaker, without interfering with untripped circuit breakers. The housing is shown including two thumbscrews 316, which can be used to secure the housing 310 to a PDU(s). In alternate examples, other fasteners may be used to removably secure the housing 310, such as latches, screws, clamps, or other techniques.

FIG. 3B is a perspective view of the device 300 including a housing 310 and a mechanism 320 according to an example. The housing 310 also includes connector 312, which may be a molex or other standard electrical connector to provide power to the solenoid 323.

FIG. 3C is a section view of the mechanism 320 according to an example. The mechanism 320 illustrates the position of the extensions 325 retracted back, in a first position. Accordingly, when issued a reset signal, the three extensions 325 can be rotated outward to reset a corresponding set of up to three tripped circuit breakers. In the example mechanism 320 of FIG. 3C, the three extensions 325 would actuate simultaneously in response to at least one circuit breaker being tripped. Thus, the extensions 325 would reset any of the three corresponding circuit breakers that had tripped, and extensions 325 whose corresponding circuit breaker had not tripped would freely rotate without interfering with untripped circuit breakers.

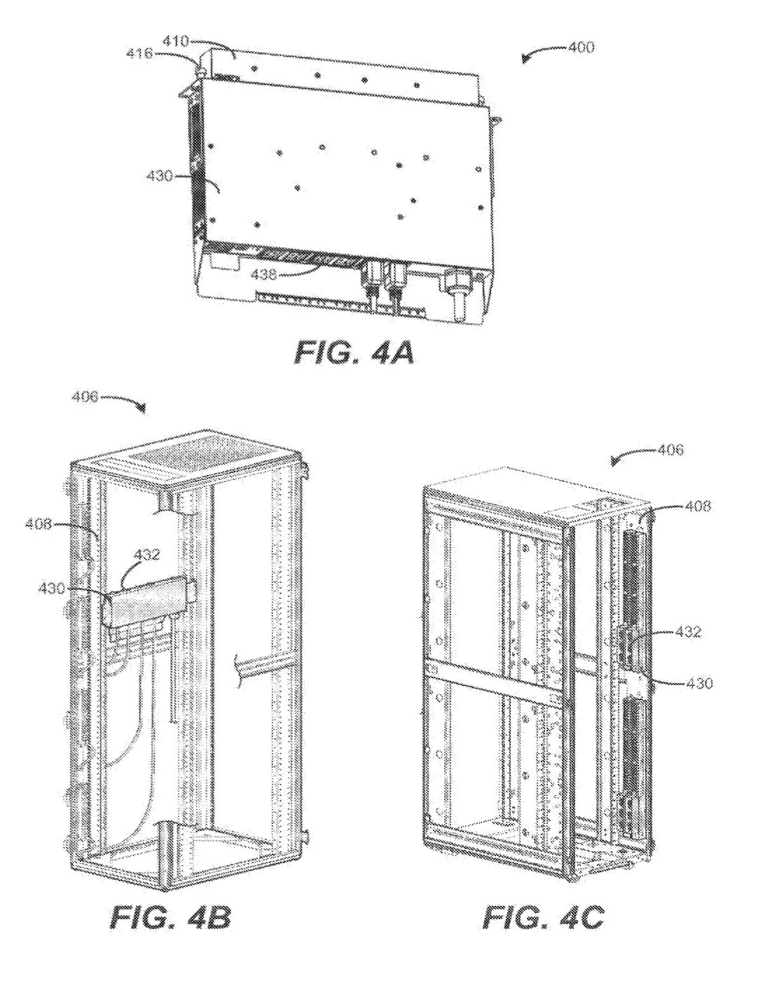

FIG. 4A is a perspective view of a system 400 including a housing and a PDU 430 according to an example. The housing 410 contains a mechanism, and is mounted to the PDU 430 via thumbscrews 416 to actuate circuit breakers (not visible in FIG. 4A, see FIGS. 4B and 4C) of the PDU 430. The circuit breakers provide power to outlets 438 visible on an underside of the PDU 430. The housing 410 (and its enclosed mechanism) and the PDU 430 are dimensioned according to a one-unit (1U) form-factor, based on a 19 inch server/rack platform whose racks are spaced 19 inches apart corresponding to 1U (with alternate examples corresponding to other rack dimensions, as appropriate).

FIG. 4B is a perspective view of a rack 406 including a PDU 430 according to an example. The rack 400 includes a plurality of rails 408, spaced to accommodate devices such as blades and/or the PDU 430. The PDU 430 is shown without the housing 410 in place, such that rocker switches of the circuit breakers 432 in the PDU 430 are visible. The rack width between rails 408 corresponds to a 19″ server platform, although other dimensions are supported.

The PDU 430 is shown positioned on a side of the rack 406 in a zero-U (0U) position, such that when other components are mounted, physical access to the PDU 430 can be blocked/restricted. The housing 410 shown in FIG. 4A, when mounted to the PDU 430, enables the circuit breakers 432 to be reset remotely (e.g., via remote switch or network interface), even if access to the circuit breakers 432 is clocked (by other equipment in the 1U position of the rack) or otherwise not easily accessible within the datacenter rack 406 (i.e., when the PDU 430 is installed between the Radio Electronics Television Manufacturers Association (RETMA) rails along a side of the rack 400 as illustrated). Access to PDU 430 also can be blocked when racks 406 are bayed together, whereby the racks 406 are attached together side by side, preventing easy access via side panels.

FIG. 4C is a perspective view of a rack 406 including a PDU 430 according to an example. The PDU 430 and its circuit breakers 432 shown in FIG. 4C are vertically oriented, having a different form-factor than the horizontally oriented PDU 430 of FIGS. 4A and 4B. The vertical PDUs 430 of FIG. 4C can be provided in multiple sizes, e.g., half-height designed to fit in a 22U and taller rack, mid-height designed to fit in a 36U and taller rack, and full-height designed to fit in a 42U and taller rack. The housing 410 and corresponding mechanism to reset the circuit breakers 432 can be sized to be mounted onto the PDU 430 to reset the circuit breakers 432. For example, a housing 410 and corresponding mechanism can include a set of six extensions to manipulate the set of six circuit breakers 432 illustrated in FIG. 4C, based on an arrangement of two columns of three extensions. Alternatively, two housings 410 can be mounted side-by-side to the PDU 430, each housing 410 containing a mechanism with three extensions to cover a column of three vertically-arranged circuit breakers 432.

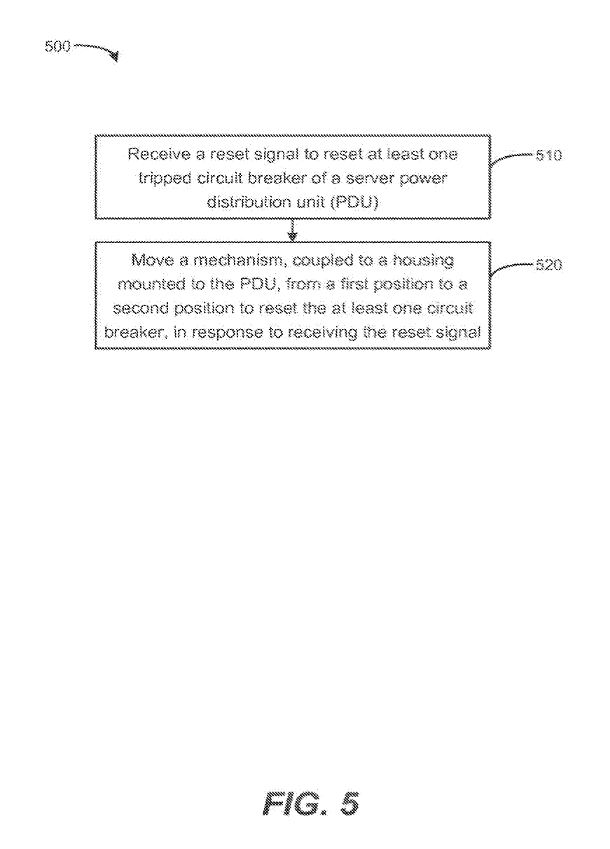

Referring to FIG. 5, a flow diagram is illustrated in accordance with various examples of the present disclosure. The flow diagram represents processes that may be utilized in conjunction with venous systems and devices as discussed with reference to the preceding figures. While illustrated in a particular order, the disclosure is not intended to be so limited. Rather, it is expressly contemplated that various processes may occur in different orders and/or simultaneously with other processes then those illustrated.

FIG. 5 is a flow chart 500 based on moving a mechanism according to an example. In block 510, a mechanism receives a reset signal to reset at least one tripped circuit breaker of a power distribution unit (PDU). For example, the mechanism can receive a power pulse from a remote switch/power supply and/or from the PDU, sufficient to actuate a solenoid. The PDU can generate the power pulse based on instructions received over a network via a network interface. In block 520, a mechanism, coupled to a housing mounted to the PDU, is moved from a rest position to a second position to reset the at least one circuit breaker, in response to receiving the reset signal. For example, the reset signal can power a solenoid to move a slider along a linear path. The slider can include rack gears to rotate a plurality of corresponding pinion gears. A pinion gear can include an extension that sweeps past its corresponding circuit breaker thereby resetting those of the circuit breakers that have tripped, without interfering with those of the circuit breakers that have not tripped.

Examples provided herein may be implemented in hardware, software, or a combination of both. Example systems can include a processor and memory resources for executing instructions stored in a tangible non-transitory medium (e.g., volatile memory, non-volatile memory, and/or computer readable media). Non-transitory computer-readable medium can be tangible and have computer-readable instructions stored thereon that are executable by a processor to implement examples according to the present disclosure.

An example system (e.g. including a controller and/or processor of a computing device) can include and/or receive a tangible non-transitory computer-readable medium storing a set of computer-readable instructions (e.g., software, firmware, etc.) to execute the methods described above and below in the claims. For example, a system can execute instructions to direct a reset engine to generate a reset signal to move a mechanism, wherein the engine(s) include any combination of hardware and/or software to execute the instructions described herein. As used herein, the processor can include one era plurality of processors such as in a parallel processing system. The memory can include memory addressable by the processor for execution of computer readable instructions. The computer readable medium can include volatile and/or non-volatile memory such as a random access memory (“RAM”), magnetic memory such as a hard disk, floppy disk, and/or tape memory, a solid state drive (“SSD”), flash memory, phase change memory, and so on.

What is claimed is:

1. A device comprising:
a housing, mountable to a power distribution unit (PDU) associated with at least one circuit breaker; and
a mechanism coupled to the housing, movable between a first position and a second position to reset the at least one circuit breaker, in response to receiving a reset signal.

2. The device of claim 1, wherein the mechanism in the first position is not in contact with a reset switch of the at least one circuit breaker, such that the reset switch of the circuit breaker is free to trip unimpeded.

3. The device of claim 1, wherein the mechanism includes a solenoid to actuate a slider including at least one rack gear corresponding to at least one pinion gear, wherein the at least one pinion gear includes a corresponding at least one extension to rotate with the at least one pinion gear to manipulate a reset switch of the at least one circuit breaker.

4. The device of claim 2, wherein the mechanism includes a plurality of pinion gears and corresponding plurality of extensions, and wherein the solenoid is to actuate the slider to simultaneously rotate the plurality of pinion gears via a corresponding plurality of rack gears of the slider.

5. The device of claim 3, wherein the solenoid is to actuate the slider with sufficient force to cause the plurality of extensions to manipulate a corresponding plurality of circuit breakers simultaneously.

6. The device of claim 1, wherein the housing further includes a connector to receive the reset signal to power the mechanism.

7. The device of claim 1, further comprising a power supply and remote switch to provide the reset signet to the mechanism.

8. The device of claim 1, wherein the housing further includes thumbscrews for mounting to the PDU.

9. The device of claim 1, wherein the housing is mountable horizontally to a horizontal PDU having a one-unit (1U) form-factor that is installable in a zero unit (0U) rack spacing between Radio Electronics Television Manufacturers Association (RETMA) rails along a side of a rack of a server.

10. The device of claim 1, wherein the housing is mountable vertically to a vertical PDU form-factor.

11. A system comprising:
a power distribution unit (PDU) associated with at least one circuit breaker;
a housing mounted to the PDU; and
a mechanism coupled to the housing, movable between a first position and a second position to reset the at least one circuit breaker, in response to receiving a reset signal.

12. The system of claim 11, further comprising a field-effect transistor (FET) disposed on a circuit board of the PDU, responsive to the reset signal to control actuation of the mechanism via a solenoid coupled to the housing.

13. The system of claim 11, further comprising a controller in the PDU to receive the reset signal via internet connection, wherein the controller is to detect whether the housing is mounted to or removed from the PDU.

14. A method, comprising:
receiving a reset signal to reset at least one tripped circuit breaker of a server power distribution unit (PDU); and
moving a mechanism, coupled to a housing mounted to the PDU, from a first position to a second position to reset the at least one circuit breaker, in response to receiving the reset signal.

15. The method of claim 14, wherein the reset signal is generated remotely from the PDU.
